(19) United States
(12) Patent Application Publication
(10) Pub. No.: US 2025/0357411 A1
(43) Pub. Date: Nov. 20, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventors: Eitaro MIYAKE, Tokyo (JP); Fumiyoshi KAWASHIRO, Tokyo (JP); Toshihiro TSUJIMURA, Tokyo (JP); Daisuke KOIKE, Tokyo (JP)

(73) Assignees: KABUSHIKI KAISHA TOSHIBA, Tokyo (JP); Toshiba Electronic Devices & Storage Corporation, Tokyo (JP)

(21) Appl. No.: 18/830,644

(22) Filed: Sep. 11, 2024

(30) Foreign Application Priority Data
May 15, 2024 (JP) 2024-079684

(51) Int. Cl. H01L 23/00; H01L 23/31

(52) U.S. Cl. CPC H01L 24/37; H01L 23/3142; H01L 24/40; H01L 2224/37013; H01L 2224/40245; H01L 2924/13055; H01L 2924/13091; H01L 2924/183; H01L 2924/30101

(57) ABSTRACT

A first conductor includes a first portion, a second portion, and a third portion. The first portion is in contact with the first electrode and has a second length in the first direction that is shorter than the first length. The second portion is located farther in a second direction than the first portion, is connected to the first portion, and has a third length in the first direction that is longer than the second length. The third portion is located farther in the second direction than the second portion, is connected to the second portion, and is exposed from a sealing resin.

### CROSS-REFERENCE TO RELATED APPLICATION

This application is based upon and claims the benefit of priority from Japanese Patent Application No. 2024-079684, filed May 15, 2024, the entire contents of which are incorporated herein by reference.

### FIELD

Embodiments described herein relate generally to a semiconductor device.

### BACKGROUND

Examples of the semiconductor device include a device having a semiconductor chip, a resin, and connectors. The semiconductor chip includes a semiconductor element such as a metal oxide semiconductor field effect transistor (MOSFET). The resin covers the semiconductor chip and the connectors. The connectors are connected to electrodes of the semiconductor chip via conductors, and are partially exposed from the resin.

### BRIEF DESCRIPTION OF DRAWINGS

FIG. 1 illustrates an appearance of a structure of a semiconductor device according to a first embodiment.

FIG. 2 illustrates an appearance of a structure of the semiconductor device according to the first embodiment.

FIG. 3 illustrates a partial structure of the semiconductor device according to the first embodiment.

FIG. 4 illustrates a structure of a cross section of a part of the semiconductor device according to the first embodiment.

FIG. 5 illustrates a structure of a plane of a semiconductor chip of the semiconductor device according to the first embodiment.

FIG. 6 illustrates a structure of a plane of a connector of the semiconductor device according to the first embodiment.

FIG. 7 illustrates a structure of a partial plane of the semiconductor device according to the first embodiment.

FIG. 8 illustrates a structure of a partial plane of the semiconductor device according to the first embodiment.

FIG. 9 illustrates a partial structure of a semiconductor device according to a modification of the first embodiment.

FIG. 10 illustrates a structure of a cross section of a part of the semiconductor device according to the modification of the first embodiment.

### DETAILED DESCRIPTION

In general, according to one embodiment, a semiconductor device includes a semiconductor chip, a first conductor, and a sealing resin. The first conductor includes a first portion, a second portion, and a third portion. The first portion is in contact with the first electrode and has a second length in the first direction that is shorter than the first length. The second portion is located farther in a second direction than the first portion, is connected to the first portion, and has a third length in the first direction that is longer than the second length. The third portion is located farther in the second direction than the second portion, is connected to the second portion, and is exposed from the sealing resin.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a layer and the ratio of thicknesses of layers may differ from those in actuality. The figures may include components which differ in relations and/or ratios of dimensions in different figures.

Hereinafter, embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a −Z direction, and down indicates the −Z direction.

### 1. First Embodiment

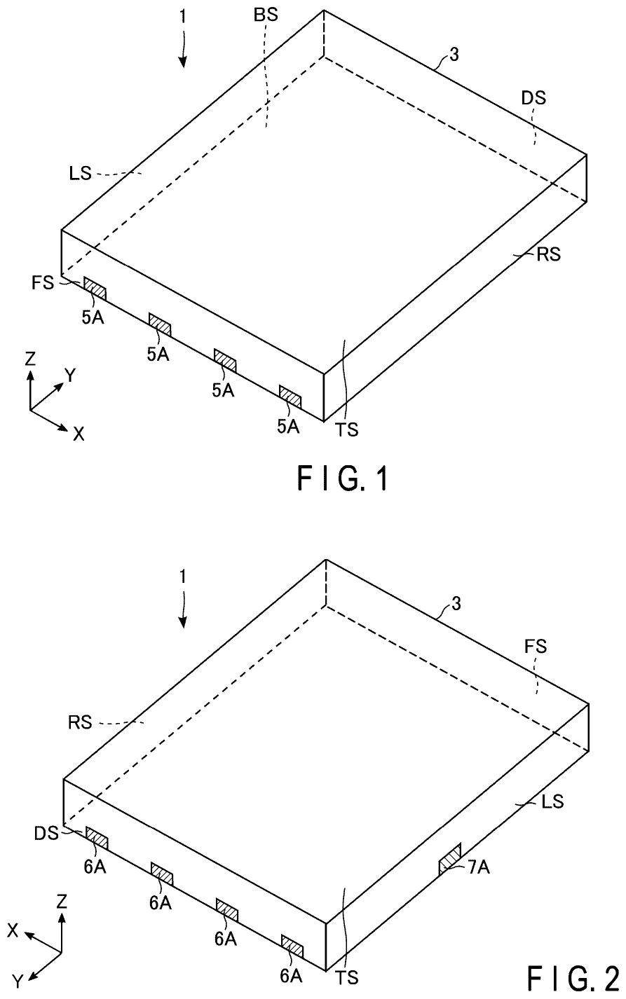

FIG. 1 illustrates an appearance of a structure of a semiconductor device according to a first embodiment. A semiconductor device 1 is configured as a semiconductor module constituting a part of another device.

The semiconductor device 1 includes a sealing body 3. The sealing body 3 includes a resin. The sealing body (sealing resin) 3 extends along an XY plane. Examples of a shape of the sealing body 3 include a hexahedron, a truncated cone, and a rectangular parallelepiped. One side of these structures may be curved. One side of these structures may be chamfered. The following description is based on an example in which the sealing body 3 has a rectangular parallelepiped shape.

The sealing body 3 covers an internal structure of the semiconductor device 1. The sealing body 3 includes surfaces BS, TS, FS, DS, LS, and RS. The surface BS and the surface TS extend along the XY plane. The surface TS is located farther in the Z direction than the surface BS.

The surface LS and the surface RS extend along the YZ plane. The surface RS is located farther in the X direction than the surface LS.

The surface FS and the surface DS extend along the ZX plane. The surface DS is located farther in the Y direction than the surface FS.

FIG. 1 illustrates the surfaces FS, RS, and TS.

The semiconductor device 1 includes a connector 5 (not illustrated). The connector 5 may also be referred to as a connection member 5. The connector 5 includes a conductor. The connector 5 includes a plurality of portions 5A. One surface of each portion 5A is exposed from the surface FS. In one example, the portions 5A are arranged in the X direction. In one example, the portions 5A are located on a lower side of the surface FS, that is, on the −Z direction side. The portions 5A function as external connection terminals that electrically connect the semiconductor device 1 to a conductor outside the semiconductor device 1.

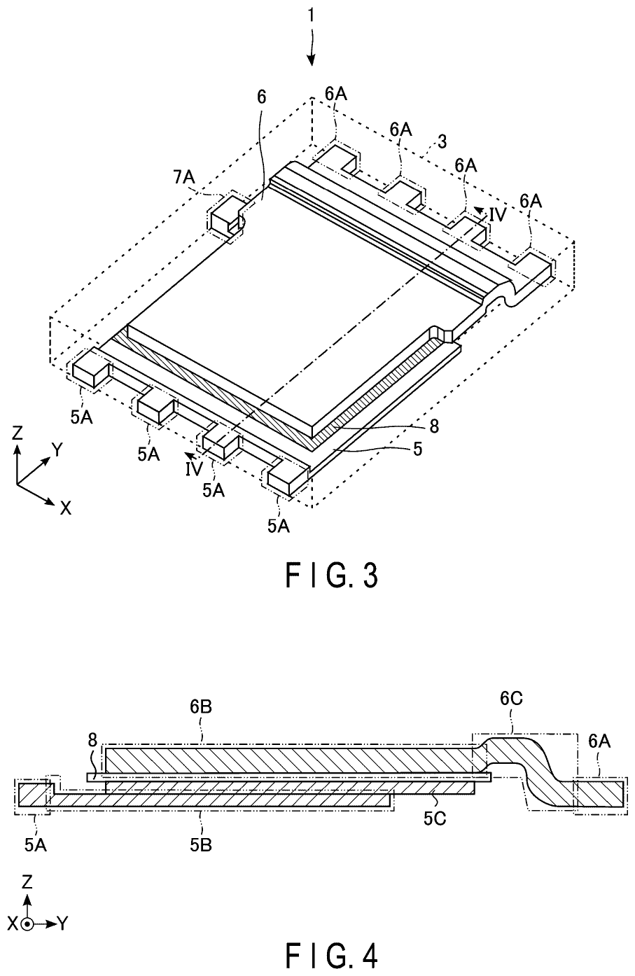

FIG. 2 illustrates an appearance of a structure of the semiconductor device according to the first embodiment. FIG. 2 illustrates the surfaces DS, LS, and BS. The semiconductor device further includes a connector 6 (not illustrated) and a connector 7 (not illustrated).

The connector 6 may also be referred to as a connection member 6. The connector 6 includes a conductor. The connector 6 includes a plurality of portions 6A. One surface of each portion 6A is exposed from the surface DS. In one example, the portions 6A are arranged in the X direction. In one example, the portions 6A are located on a lower side of the surface BS, that is, on the −Z direction side. The portions 6A function as external connection terminals that electrically connect the semiconductor device 1 to a conductor outside the semiconductor device 1. As described above with reference to FIG. 1, the semiconductor device 1 may constitute a part of another device, and eventually may constitute a part of a circuit realized by the device. In a case where the semiconductor device 1 configures a part of a circuit of another device, the portions 6A are connected to a node having a potential higher than the potential of the node to which the portions 5A of the circuit are connected. Therefore, the connector 6 is connected to a node having a potential higher than the potential of the node to which the connector 5 is connected in the circuit.

The connector 7 may also be referred to as a connection member 7. The connector 7 includes a conductor. The connector 7 includes a portion 7A. One surface of the portion 7A is exposed from the sealing body 3, and in one example, is exposed from the surface RS. In one example, the portion 7A is located in a lower portion of the surface RS. The portion 7A functions as an external connection terminal that electrically connects the semiconductor device 1 to a conductor outside the semiconductor device 1.

FIG. 3 illustrates a partial structure of the semiconductor device according to the first embodiment. FIG. 3 shows the same region as that shown in FIG. 1. FIG. 3 illustrates an internal structure of the semiconductor device 1. In FIG. 3, the sealing body 3 is indicated by a dotted line.

The connector 5 extends along the XY plane and extends in the Y direction. The connector 5 includes the portions 5A as described above with reference to FIG. 1 and further includes other portions. The other portions will be described later.

The semiconductor device 1 further includes a semiconductor chip 8. The semiconductor chip 8 is a chip including a semiconductor element. Examples of the semiconductor element include an n-type MOSFET and an insulated gate bipolar transistor (IGBT). The following description is based on an example of a MOSFET. The semiconductor chip 8 extends along the XY plane. The semiconductor chip 8 is located on an upper surface (that is, a surface on the Z-direction side) of the connector 5.

The connector 6 extends along the XY plane and extends in the Y direction. The connector 6 includes the portions 6A as described above with reference to FIG. 2 and further includes other portions. A part of the connector 6 is located on the upper surface of the semiconductor chip 8.

FIG. 4 illustrates a structure of a cross section of a part of the semiconductor device according to the first embodiment. FIG. 4 illustrates a structure taken along line IV-IV in FIG. 3.

The connector 5 further includes portions 5B and 5C. The portion 5B is connected to or continuous with, that is, is integrally formed with the portions 5A. The portion 5C may be continuous with the set of portions 5A and 5B, or may be formed separately from and joined with the set of portions 5A and 5B.

The portion 5B extends along the XY plane. In the portion 5B, a left end (that is, an end on the −X direction side) has a height higher than other regions. The portion 5B is connected to the portions 5A at the left end. A right end (that is, an end on the X direction side) of the portion 5B is located below the semiconductor chip. In one example, the right end of the portion 5B is located farther on the Y direction side than a center of an imaginary line connecting the left end and the right end of the semiconductor chip 8.

The portion 5C extends along the XY plane. A lower surface (that is, a surface on the −Z direction side) of the portion 5C is connected to or continuous with an upper surface (that is, a surface on the Z-direction side) of the portion 5B. A left end of the portion 5C is spaced from the portions 5A. A right end of the portion 5C is located farther in the Y direction than the right end of the portion 5B.

The semiconductor chip 8 is located on an upper surface of the portion 5C.

The semiconductor chip 8 is located directly above the portion 5B. A left end of the semiconductor chip 8 is located farther in the −Y direction than the left end of the portion 5C. A right end of the semiconductor chip 8 is located farther in the Y direction than the right end of the portion 5C.

The connector 6 further includes portions 6B and 6C. The portion 6B extends along the XY plane. The portion 6B is located directly above the semiconductor chip 8. A left end of the portion 6B is located farther in the Y direction than the left end of the semiconductor chip 8.

The portion 6C is connected to or continuous with the right end of the portion 6B at the left end. The portion 6C is curved. A right end of the portion 6C is located farther on a lower side (that is, in the −Z direction) than the left end of the portion 6B. The portion 6C is connected to or continuous with the portions 6A at the right end.

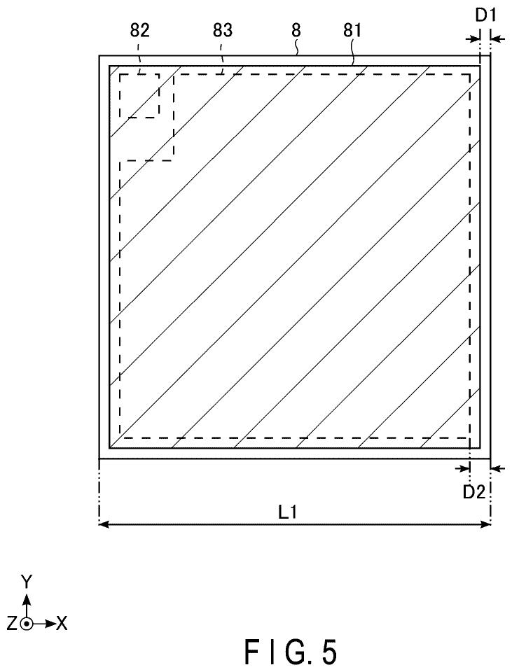

FIG. 5 illustrates a structure of a plane of a semiconductor chip of the semiconductor device according to the first embodiment. FIG. 5 illustrates a structure when the semiconductor chip 8 is viewed in the −Z direction along the XY plane.

In one example, the semiconductor chip 8 has a quadrilateral shape or a rectangular shape. Each of four sides extends in the X direction or the Y direction. The semiconductor chip 8 has a length L1 in the X direction, that is, along the x axis. The semiconductor chip 8 includes a drain electrode 81, a gate electrode 82, and a source electrode 83.

The drain electrode 81 is exposed on an upper surface (that is, a surface on the Z-direction side) of the semiconductor chip 8. The drain electrode 81 has a shape along the sides of the semiconductor chip 8. In one example, the drain electrode 81 has a shape similar to the shape of the semiconductor chip 8. In one example, each side of the drain electrode 81 faces a side of the semiconductor chip 8. In one example, at least one side of the drain electrode 81 has a distance D1 from one side of the semiconductor chip 8. In one example, each side of the drain electrode 81 has the distance D1 from one side of the semiconductor chip 8. The drain electrode 81 is connected to one end of a transistor and is connected to a drain of a MOSFET. In a case where the semiconductor chip 8 includes an IGBT, the drain electrode 81 is a collector electrode and is connected to a collector of the IGBT.

The gate electrode 82 is exposed on a lower surface (that is, a surface on the −Z direction side) of the semiconductor chip 8. In one example, the gate electrode 82 faces one side of the semiconductor chip 8. In one example, the gate electrode 82 faces an upper end (that is, an end on the Y direction side) of the semiconductor chip 8 and faces a left end (that is, an end on the −X direction side) of the semiconductor chip 8. The gate electrode 82 is connected to a gate of a MOSFET or an IGBT.

The source electrode 83 is exposed on the lower surface of the semiconductor chip 8. The source electrode 83 spreads over a region other than a region where the gate electrode 82 is exposed on the lower surface of the semiconductor chip 8. The source electrode 83 is spaced from the gate electrode 82. The source electrode 83 may have any shape as long as the source electrode 83 spreads in a vicinity of the gate electrode 82 over a region other than the region of the gate electrode 82. In one example, the source electrode 83 has a quadrilateral shape generally along the shape of the semiconductor chip 8, and has a quadrilateral notch around the gate electrode 82. The notch may have a shape in which a plurality of quadrilaterals are connected. The source electrode 83 is connected to another end of the transistor and is connected to a source of the MOSFET. In a case where the semiconductor chip 8 includes an IGBT, the source electrode 83 is an emitter electrode and is connected to an emitter of the IGBT.

In one example, at least one side of the source electrode 83 has a distance D2 from one side of the semiconductor chip 8. In one example, each of all sides of the source electrode 83 except for the side facing the gate electrode 82 has a distance D2 from one side of the semiconductor chip 8. The semiconductor chip 8 needs to be provided with a termination structure around the source electrode or the emitter electrode. The termination structure is a structure provided at the termination, and has a structure different from the structure in other regions. Unlike the drain electrode and the collector electrode, the source electrode and the emitter electrode cannot be formed near the edge of the semiconductor chip 8. Based on this, the distance D2 is larger than the distance D1.

As described so far, the source electrode 83 is located on a lower surface (that is, a surface on the −Z direction side) of the semiconductor chip 8, and the drain electrode 81 (and the gate electrode 82) is located on the upper surface of the semiconductor chip 8. Therefore, the semiconductor device 1 includes the connector 5 connected to the source electrode 83 on the −Z direction side. Such a structure in which the source electrode and in turn the connector connected to the source electrode are located on the lower surface side of the semiconductor chip is referred to as a source-down structure.

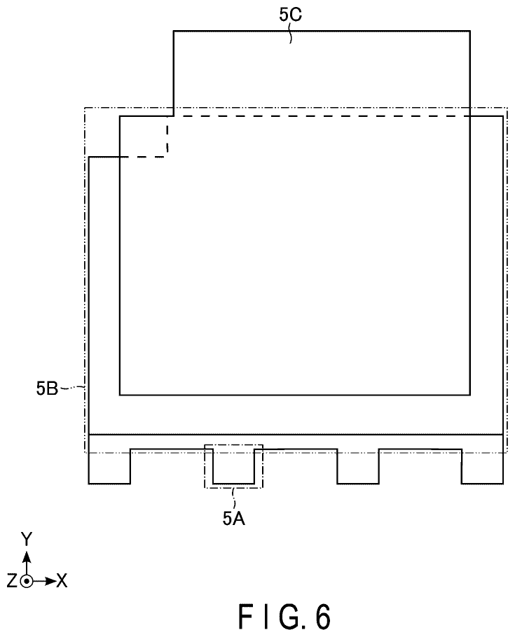

FIG. 6 illustrates a structure of a plane of the connector 5 of the semiconductor device according to the first embodiment. FIG. 6 illustrates a structure in a case where a part of the semiconductor device 1 is viewed in the −Z direction along the XY plane.

The portion 5B has a shape having a notch in a vicinity of a region located in the −Z direction of the gate electrode 82 (not illustrated). In one example, the portion 5B has a generally quadrilateral shape and has a shape having a notch in the vicinity of a region located in the −Z direction of the gate electrode 82 (not illustrated).

The portion 5C has a shape having a notch in the vicinity of a region located in the −Z direction of the gate electrode 82 (not illustrated). In one example, the portion 5C has a generally quadrilateral shape and has a shape having a notch in the vicinity of a region located in the −Z direction of the gate electrode 82 (not illustrated). An end of the portion 5C on a Y direction side (that is, the upper side), that is, an upper end is located farther in the Y direction than the upper end of the portion 5B.

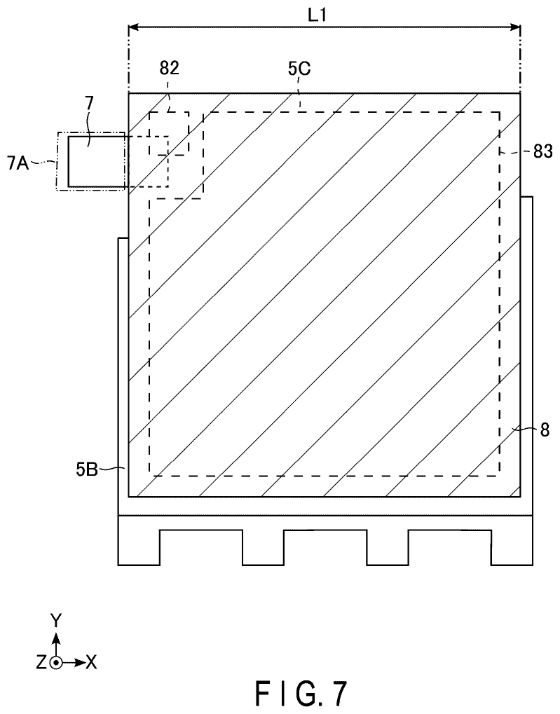

FIG. 7 illustrates a structure of a partial plane of the semiconductor device according to the first embodiment. FIG. 7 illustrates a portion on the −z direction side of the internal structure of the semiconductor device 1. FIG. 7 illustrates a structure in a case where the same region as the region illustrated in FIG. 6 is viewed in the −Z direction along the XY plane.

The lower end of the semiconductor chip 8 is located farther in the Y direction than the lower end of the portion 5B. The length L1 of the semiconductor chip 8 is smaller than a length (that is, a length along the X axis) of the portion 5B in the X direction. In one example, the left end of the semiconductor chip 8 is located farther in the X direction than the left end of the portion 5B. In one example, the right end of the semiconductor chip 8 is located farther in the −X direction than the right end of the portion 5B.

The portion 5C overlaps the source electrode 83. In one example, an outline of the portion 5C is along a contour of the source electrode 83. In one example, the portion 5C is substantially the same as and substantially matches the shape of the source electrode 83.

The connector 7 overlaps the gate electrode 82. The connector 7 is in contact with the gate electrode 82 at a portion overlapping the gate electrode 82.

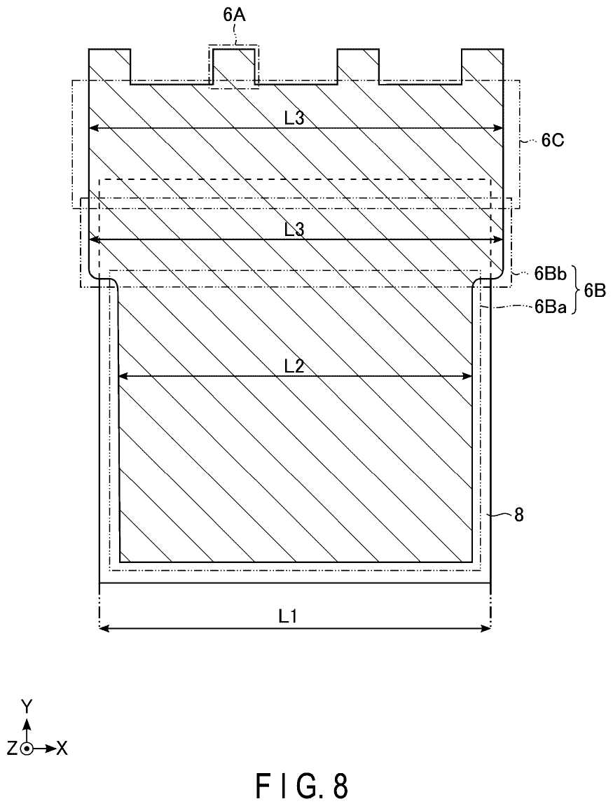

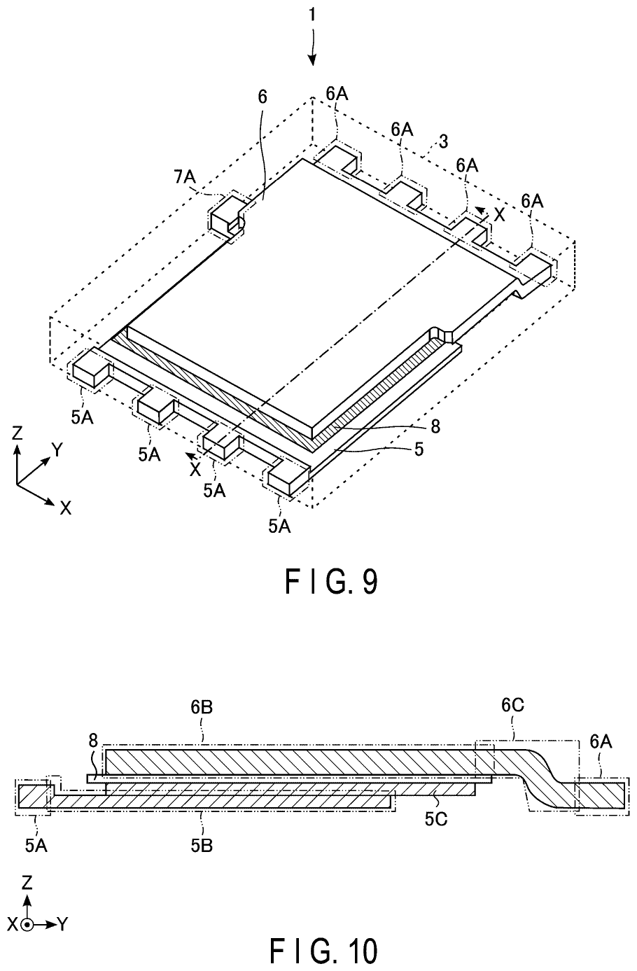

FIG. 8 illustrates a structure of a partial plane of the semiconductor device according to the first embodiment. FIG. 8 illustrates a portion on the Z direction side of the internal structure of the semiconductor device 1. FIG. 8 illustrates a structure when the same region as the region illustrated in FIGS. 6 and 7 is viewed in the −Z direction along the XY plane.

The portion 6B includes a portion 6Ba and a portion 6Bb. The portion 6Ba occupies a portion on the −Y direction side (that is, a lower side) of the portion 6B. In one example, the portion 6Ba has a quadrilateral shape. A lower end of the portion 6Ba is located farther in the Y direction than the lower end of the semiconductor chip 8. In one example, a left end of the portion 6Ba is located farther in the X direction than a left end of the semiconductor chip 8, and a right end of the portion 6Ba is located farther in the −X direction than a right end of the semiconductor chip 8. Only one of the left end and the right end of the portion 6Ba may be located inside the ends of the semiconductor chip 8. That is, the left end of the portion 6Ba may be located farther in the X direction than the left end of the semiconductor chip 8, or the right end of the portion 6Ba may be located farther in the −X direction than the right end of the semiconductor chip 8. The portion 6Ba has a length L2 in the X direction (that is, along the x-axis). The length L2 is smaller than the length L1 of the semiconductor chip 8.

The portion 6Bb occupies a portion on the Y direction side (that is, an upper side) of the portion 6B. In one example, the portion 6Bb has a quadrilateral shape. The portion 6Bb, at a lower end, is connected to or continuous with an upper end of the portion 6Ba. The portion 6Bb has a length L3 in the X direction. The length L3 is longer than the lengths L1 and L2. In one example, a left end of the portion 6Bb is located farther in the −X direction than the left end of the semiconductor chip 8. In one example, a right end of the portion 6Bb is located farther in the X direction than the right end of the semiconductor chip 8.

The portion 6Bb preferably overlaps the semiconductor chip 8 and the drain electrode 81 over a wider area. From this viewpoint, in one example, a boundary between the portion 6Bb and the portion 6Ba is located farther in the −Y direction than a midpoint of a virtual line connecting the upper end and the lower end of the semiconductor chip 8. The portion 6Ba may not be provided, that is, the portion 6B may have a length L2 from the upper end to the lower end.

The portion 6C has a length L3 along the x-axis.

As described above with reference to FIG. 2, in a case where the semiconductor device 1 configures a part of a circuit of another device, the connector 6 is connected to a node having a potential higher than the potential of the node to which the connector 5 is connected of the circuit. Thus, while the device is operating, current flows in from portion 6A and reaches drain electrode 81 via portions 6C and 6Bb. That is, the portions 6C and 6Bb constitute a current path between the portion 6A and the drain electrode 81.

According to the first embodiment, as described below, the semiconductor device 1 has a small electrical resistance. As a structure for comparison, it is conceivable that the connector 6 has the same length L2 as the portion 6Ba in the portions 6C and 6Bb. However, in this case, the areas of the portions 6C and 6Bb are small, and thus the current path between the portion 6A and the drain electrode 81 is small.

On the other hand, according to the first embodiment, the portions 6C and 6Bb have the length L3 longer than the length L2. Therefore, between the portion 6A and the drain electrode 81, the resistance is smaller than that in the case of the structure for comparison.

In addition, the portion 6Ba has a length L2, and the length L2 is smaller than the length L1 of the semiconductor chip 8. Therefore, in a case where the semiconductor chip 8 and the connector 6 are stacked along the XY plane, at least one of the left end and the right end of the semiconductor chip 8 is exposed from the connector 6 regardless of the relative positional relationship between the semiconductor chip 8 and the connector 6. Therefore, when the connector 6 is disposed on the semiconductor chip 8 while the semiconductor device 1 is assembled, the position and orientation of the semiconductor chip 8 can be visually recognized through the position of the ends of the semiconductor chip 8. This facilitates assembly of the semiconductor device 1. That is, according to the first embodiment, the semiconductor device 1 is provided so as to have a small resistance and capable of being easily assembled.

A structure is conceivable in which the semiconductor chip 8 is disposed such that the source electrode 83 and the gate electrode 82 are located on an upper surface (that is, a surface on the Z direction side) (so-called drain-down structure), and the connector 6 is connected to the source electrode 83. However, with such a structure, the portion 6Bb of the connector 6 may come into contact with a region including the end of the chip 8. As a result of the contact, the source and the drain of the MOSFET of the semiconductor chip 8 are short-circuited. Therefore, the connector 6 cannot be applied to the drain-down structure. On the other hand, according to the first embodiment, since the source electrode 83 is located on a lower surface (that is, a source-down structure), it is possible to achieve the semiconductor device 1 that has a small resistance and that can be easily assembled while avoiding an unintended short circuit.

FIG. 9 illustrates a partial structure of a semiconductor device according to a modification of the first embodiment. FIG. 9 shows the same regions as those shown in FIG. 1 and FIG. 3. Similarly to FIG. 3, FIG. 9 illustrates an internal structure of the semiconductor device 1, and the sealing body 3 is indicated by a dotted line. FIG. 10 illustrates a structure of a cross section of a part of the semiconductor device according to the modification of the first embodiment, and FIG. 10 illustrates a structure taken along line X-X in FIG. 9.

As shown in FIG. 9 and FIG. 10, the portion 6C of the connector 6 may not be curved. That is, the portion 6C has a shape in which two sub-portions having an arc shape are connected, in other words, has a shape in which an S-shape is extended. In other words, the portion 6C extends in the Y direction, is curved to the semiconductor chip 8 or the connector 5 without being curved in the Z direction in the direction away from the semiconductor chip 8, and is connected to the portion 6A extending in the Y direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor chip that includes a first surface and a second surface opposite to the first surface, includes a first electrode exposed on the first surface, includes a second electrode exposed on the second surface, includes a third electrode exposed on the second surface and spaced from the second electrode, and has a first length in a first direction;
a first conductor that is in contact with the first electrode; and
a sealing resin that surrounds the semiconductor chip and surrounds a part of the first conductor, wherein
the first conductor includes a first portion, a second portion, and a third portion,
the first portion is in contact with the first electrode and has a second length in the first direction that is shorter than the first length,
the second portion is located farther in a second direction than the first portion, is connected to the first portion, and has a third length in the first direction that is longer than the second length, and
the third portion is located farther in the second direction than the second portion, is connected to the second portion, and is exposed from the sealing resin.

2. The semiconductor device according to claim 1, wherein
the third length is longer than the first length.

3. The semiconductor device according to claim 1, further comprising:
a second conductor that is in contact with the second electrode, includes a portion surrounded by the sealing resin, and includes a portion exposed from the sealing resin; and
a third conductor that is in contact with the third electrode, includes a portion surrounded by the sealing resin, and includes a portion exposed from the sealing resin.

4. The semiconductor device according to claim 1, wherein
the first electrode has an outline that follows an outline of the semiconductor chip,
an end of the semiconductor chip has a first distance from an end of the first electrode and a second distance from an end of the third electrode, and
the second distance is smaller than the first distance.

5. The semiconductor device according to claim 4, wherein
each of all sides of the third electrode except for a side facing the second electrode has the second distance from a side of the semiconductor chip.

6. The semiconductor device according to claim 1, wherein
the semiconductor chip includes a first end and a second end,
the second end is located farther in the first direction than the first end,
the second portion includes a third end and a fourth end,
the first end is located farther in the first direction than the third end, and
the fourth end is located farther in the first direction than the second end.

7. The semiconductor device according to claim 1, further comprising:
a second conductor that is in contact with the second electrode, includes a portion surrounded by the sealing resin, and includes a portion exposed from the sealing resin; and
a third conductor that is in contact with the third electrode, includes a portion surrounded by the sealing resin, and includes a portion exposed from the sealing resin, wherein
the third length is longer than the first length,
the first electrode has an outline that follows an outline of the semiconductor chip,
an end of the semiconductor chip has a first distance from an end of the first electrode and a second distance from an end of the third electrode,
the second distance is smaller than the first distance,
the semiconductor chip includes a first end and a second end,
the second end is located farther in the first direction than the first end,
the second portion includes a third end and a fourth end,
the first end is located farther in the first direction than the third end, and
the fourth end is located farther in the first direction than the second end.

8. The semiconductor device according to claim 1, wherein
the semiconductor chip includes a transistor,
one end of the transistor is connected to the first electrode,
a gate of the transistor is connected to the second electrode, and
another end of the transistor is connected to the third electrode.

9. The semiconductor device according to claim 2, wherein
the semiconductor chip includes a transistor,
one end of the transistor is connected to the first electrode,
a gate of the transistor is connected to the second electrode, and
another end of the transistor is connected to the third electrode.

10. The semiconductor device according to claim 3, wherein
the semiconductor chip includes a transistor,
one end of the transistor is connected to the first electrode,
a gate of the transistor is connected to the second electrode, and
another end of the transistor is connected to the third electrode.

11. The semiconductor device according to claim 4, wherein
the semiconductor chip includes a transistor,
one end of the transistor is connected to the first electrode,
a gate of the transistor is connected to the second electrode, and
another end of the transistor is connected to the third electrode.

12. The semiconductor device according to claim 5, wherein
the semiconductor chip includes a transistor,
one end of the transistor is connected to the first electrode,
a gate of the transistor is connected to the second electrode, and
another end of the transistor is connected to the third electrode.

13. The semiconductor device according to claim 6, wherein
the semiconductor chip includes a transistor,
one end of the transistor is connected to the first electrode,
a gate of the transistor is connected to the second electrode, and
another end of the transistor is connected to the third electrode.

14. The semiconductor device according to claim 7, wherein
the semiconductor chip includes a transistor,
one end of the transistor is connected to the first electrode,
a gate of the transistor is connected to the second electrode, and
another end of the transistor is connected to the third electrode.
